(19) United States
(12) Patent Application Publication
(10) Pub. No.: US 2005/0221592 A1
(43) Pub. Date: Oct. 6, 2005

(54) Method of growing III-V compound semiconductor layer, substrate product, and semiconductor device

(76) Inventors: Takashi Ishizuka, Itami-shi (JP); Tadashi Saito, Itami-shi (JP); Shigenori Takagishi, Itami-shi (JP)

Correspondence Address: MCDERMOTT WILL & EMERY LLP, 600 13TH STREET, N.W., WASHINGTON, DC, 20005-3096, US

(21) Appl. No.: 11/089,038

(22) Filed: Mar. 25, 2005

Related U.S. Application Data
(60) Provisional application No. 60/556,371, filed on Mar. 26, 2004.

(30) Foreign Application Priority Data
Jun. 3, 2004 (JP) P2004-166254

(51) Int. Cl. H01L 27/15; H01L 21/36; H01L 21/20; C30B 1/00; H01L 33/00; H01L 31/12; H01L 29/26

(52) U.S. Cl. 438/483

(57) ABSTRACT

A method for growing a GaInNAs layer on a supporting base comprises the steps of supplying antimony to the surface of a supporting base, and growing a GaInNAs layer on the surface after supplying the antimony. The GaInNAs layer is grown after supplying the antimony. In the step of supplying the antimony, raw materials comprising Group V elements are simultaneously supplied in addition to the antimony. The Group V elements are at least either arsenic (As) or phosphorus (P). The GaInNAs layer is grown by any of the MOCVD method, MBE method, or epitaxial growth method.

### BACKGROUND OF THE INVENTION

1. Field of the Invention

The present invention relates to a method for growing a GaInNAs layer, and to an epitaxial wafer, a semiconductor optical device, a semiconductor laser, a light receiving device, a high electron mobility transistor, a heterojunction bipolar transistor, and a semiconductor device.

2. Related Background Art

Literature 1 (Japanese Patent 2003-532276) shows that when growing crystals which have GaInNAs quantum well structures, the GaInNAs quantum well layer grows in locations where antimony is present. At this time, the adulteration by antimony in the GaInNAs quantum well is at a level which can be ignored.

### SUMMARY OF THE INVENTION

There is a need for growing high quality III-V compound semiconductors containing nitrogen or III-V compound semiconductors containing nitrogen and gallium, indium or arsenic. An example of this type of III-V compound semiconductor is a GaInNAs semiconductor.

According to Literature 1, when growing GaInNAs quantum well structures using the MOVPE method or the MBE method, the GaInNAs layer grows in locations where antimony is present. If the adulteration by antimony in the GaInNAs quantum well structures is small enough to be ignored, the effect of improving the crystal properties by the addition of antimony will be extremely small. When antimony is added to GaInNAs with the MBE method, the antimony accounts for approximately 2% of the Group V elements in the formulation, a level which cannot be ignored, and at first there is an improved effect in the crystal properties. Furthermore, with the MOVPE method, even with minimal levels of antimony adulteration, a reduction in the GaInNAs emission wavelength occurs, and the improvement in the crystal properties are not that significant.

With the foregoing in view, it is an object of the present invention to provide a method for growing high quality crystals of a III-V compound semiconductor containing nitrogen and gallium, indium, or arsenic, and a further object of the present invention is to provide an epitaxial wafer comprising a film of III-V compound semiconductor, a semiconductor optical device comprising a III-V compound semiconductor layer, a semiconductor laser comprising a III-V compound semiconductor layer, a light receiving device comprising a III-V compound semiconductor layer, a high electron mobility transistor comprising a III-V compound semiconductor layer, a heterojunction bipolar transistor comprising a III-V compound semiconductor layer, and a semiconductor device comprising a III-V compound semiconductor layer.

One aspect of the present invention is a method to grow a GaInNAs layer on a supporting base. This method comprises the steps of: providing or attaching antimony to the surface of the supporting base; and after the antimony has been attached or provided, growing the GaInNAs layer on the surface.

In the method of the present invention, the GaInNAs layer is preferably grown after the antimony is supplied.

In the method of the present invention, a step of supplying raw materials including group V elements in addition to antimony at the same time as the step of supplying or attaching the antimony is preferable.

In the method of the present invention, the group V elements preferably includes at least either arsenic (As) or phosphorus (P).

In the method of the present invention, the crystal growth preferably uses any one of the MOCVD method, the MBE method, or the epitaxial growth method.

In the present invention, the sustain time for the supplied antimony on the surface of the supporting base is preferably no less than 1 second.

In the present invention, in the step of supplying (attaching) antimony, the quantity X of antimony supplied is preferably greater than or equal to 0 and less than or equal to 1 (0.0≦X≦1.0), where X=(quantity of antimony supplied per unit time)/((quantity of antimony supplied per unit time)+(quantity of arsenic supplied per unit)).

In the method of the present invention, the supporting base preferably comprises a GaAs substrate.

In the method of the present invention, the supporting base preferably comprises an InP substrate.

According to another aspect of the present invention, an epitaxial wafer comprises a substrate and a GaInNAs layer provided on that substrate, and the GaInNAs layer is grown by any one of the aforementioned methods.

According to another aspect of the present invention, a semiconductor device comprises a GaInNAs layer provided on a supporting base, and the GaInNAs layer is grown by any one of the aforementioned methods.

In a preferred embodiment, a semiconductor optical device comprises a first conductive semiconductor layer, a second conductive semiconductor layer, and an active layer comprising a GaInNAs layer and provided between the first conductive semiconductor layer and the second conductive semiconductor layer, and the GaInNAs layer is grown by any one of the aforementioned methods.

In a preferred embodiment, a semiconductor laser comprises a first clad layer, a second clad layer, and an active layer comprising a GaInNAs layer and provided between the first clad layer and the second clad layer, and the GaInNAs layer is grown by any one of the aforementioned methods.

In a preferred embodiment, a light receiving device comprises a light receiving semiconductor layer comprising a GaInNAs layer and provided on a supporting base, and the GaInNAs layer is grown by any one of the aforementioned methods.

In a preferred embodiment, a high electron mobility transistor comprises a first semiconductor layer through which a carrier flows provided on a supporting base, one or more second semiconductor layers, a first electrode which controls the carrier flows provided on the first and second semiconductor layers, a second electrode provided on the first and second semiconductor layers, the third electrode provided on the first and second semiconductor layers, wherein at least one of the first or second semiconductor layers comprises a GaInNAs layer, and the GaInNAs layer is grown by any one of the aforementioned methods.

In a preferred embodiment, a heterojunction bipolar transistor comprises an emitter layer provided on a supporting base, a collector layer provided on the supporting base, and a base layer provided between the collector layer and the emitter layer, wherein at least the emitter layer, the collector layer, or the base layer are comprising a GaInNAs layer, and the GaInNAs layer is grown by any one of the aforementioned methods.

### BRIEF DESCRIPTION OF THE DRAWINGS

FIG. 1 is a drawing showing a quantum well structure formed on a substrate;

FIG. 2 is a drawing showing a time chart showing the raw material gas flow for the crystal growth of a GaInNAs quantum well structure;

FIG. 3 is a drawing showing the photoluminescence measurement results for a quantum well structure;

FIG. 4 is a drawing showing a time chart showing the raw material gas flow for the crystal growth of a GaInNAs quantum well structure;

FIG. 5 is a drawing showing the photoluminescence measurement results for a quantum well structure;

FIG. 6 is a drawing showing the photoluminescence (PL) strength of GaInNAs which has been annealed at 700° C.;

FIG. 7A is a drawing showing an epitaxial wafer;

FIG. 7B is a drawing showing a semiconductor optical device;

FIG. 7C is a drawing showing a semiconductor laser;

FIG. 7D is a drawing showing a light receiving device;

FIG. 7E is a drawing showing a high electron mobility transistor;

FIG. 7F is a drawing showing a heterojunction bipolar transistor;

FIG. 8 is a drawing showing the major physical values of antimony raw material;

FIG. 9 is a drawing showing the growth conditions, growth sequence, and created device of the first test;

FIG. 10 is a drawing showing the structure of GaInNAs crystals grown while supplying TMSb at the same time as the GaInNAs layer growth;

FIG. 11 is a drawing showing the photoluminescence properties of a GaInNAs layer grown while supplying TMSb at the same time as the GaInNAs layer growth;

FIG. 12 is a drawing showing the growth conditions, growth sequence, and created device of the second test;

FIG. 13 is a drawing showing the photoluminescence properties of a device created by the second test;

FIG. 14 is a drawing showing the photoluminescence (PL) strength of GaInNAs which has been annealed at 700° C.; and

FIG. 15 is a drawing showing AFM evaluation results.

### DESCRIPTION OF THE PREFERRED EMBODIMENTS

Preferred embodiments of the present invention will be described while referring to the drawings. Where possible, the same code has been used for identical or similar parts, and the duplicate description has been omitted.

### First Embodiment

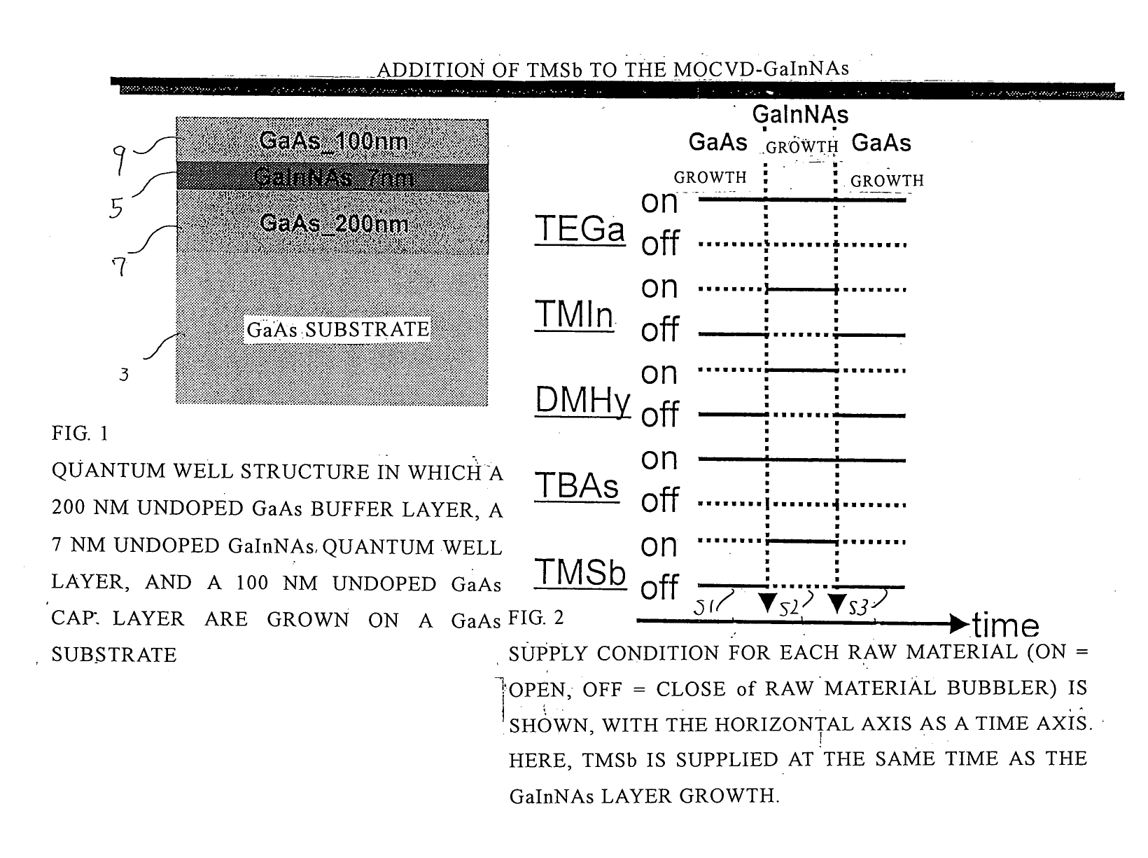

FIG. 1 is a drawing showing a quantum well structure formed on a substrate. A substrate 3 has a GaInNAs well structure 5, a GaAs layer 7, and a GaAs layer 9.

[Test Case 1]

In a preferred embodiment, GaInNAs/GaAs single quantum well (SQW) structure crystal is grown on a GaAs substrate using the MOVPE method. TEGa, TMIn, DMHy, and TBAs are used as the raw materials for Ga, In, N, and As respectively. The substrate is a silicon doped GaAs (100) surface 2° off substrate. A 200 nanometer (200 nm) undoped GaAs buffer layer, followed by a 7 nanometer (7 nm) undoped GaInNAs quantum well structure, and a 100 nanometer (100 nm) undoped GaAs cap layer are grown on a GaAs substrate. The growth temperature of the GaInNAs quantum well structure is 510° C., the growth speed is 1 μm/hour, the DMHy/(DMHy+TBAs) ratio is 0.97, and the growth pressure is 76 torr. The composition of the GaInNAs quantum well layer is 66% Ga and 34% In.

After epitaxial growth of these layers, thermal annealing is performed using a MOVPE oven (in-situ). The thermal annealing is performed in a TBAs environment (TBAs flow rate: 1.6E-4 mole/min) at three levels of annealing temperatures, namely 570° C., 620° C., and 670° C. The annealing time is 10 minutes. For comparison, an “as-grown” test sample which is not thermally annealed is also produced at the same time.

FIG. 2 is a drawing showing a time chart showing the raw material gas flow for the crystal growth of a GaInNAs quantum well structure. With the crystal growth of this GaInNAs quantum well layer, TMSb (trimethyl antimony) which is the antimony raw material is supplied while the GaInNAs layer is grown. Three levels of antimony are supplied, namely 0.06%, 0.15%, and 0.59%, using the ratio [TMSb]/([TMSb]+[TBAs]) as a parameter. The GaInNAs layer growth is continuous after the growth of the GaAs buffer layer on the bottom. For comparison, a test sample (reference) where TMSb is not supplied is also produced at the same time.

In Process S1, a first GaAs film is formed. At this time, TEGa and TBAs is used as the raw material gas. In Process S2, the GaInNAs film is formed. At this time, TEGa, TMIn, DMHy, TBAs, and TMSb are used for the raw material gas. In Process S3, the second GaAs film is formed. At this time, TEGa and TBAs are used for the raw material gas.

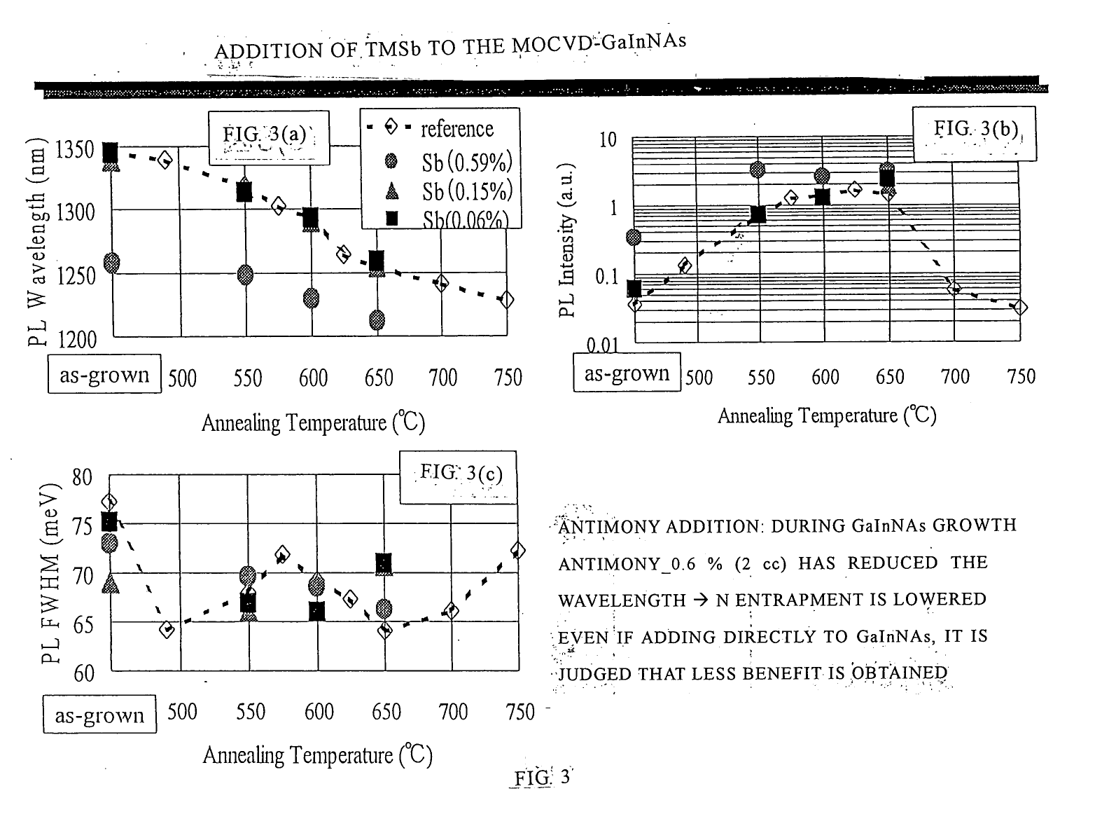

The optical properties of these GaInNAs/GaAs quantum well structure crystals is evaluated the by the photoluminescence (PL: Photoluminescence) at room temperature. FIG. 3 is a drawing showing the PL measurement results for a quantum well structure.

FIG. 3B shows the thermal annealing temperature dependency of the photoluminescence strength. If the quantity of antimony supplied is small ([TMSb]/([TMSb]+[TBAs]) ratio is 0.15% or 0.06%), there will be almost no difference from the reference in the annealing temperature dependency of the PL strength, and the improvement in the crystal properties of the GaInNAs induced by the addition of antimony is thought to be extremely small. If the quantity of antimony is increased ([TMSb]/([TMSb]+[TBAs]) ratio is 0.59%), there is a great difference in the PL strength at each annealing temperature. However, as can be seen from the results of the thermal annealing temperature dependency of the PL wave length shown in FIG. 3A, the PL wave length has a tendency to shorten as the supply quantity of antimony increases, and the N entrapment effect on the GaInNAs layer is thought to be reduced. Furthermore, from the results of the thermal annealing temperature dependency on the photoluminescence full width at half maximum (FWHM) shown in FIG. 3C, there is not a big difference when compared to the reference. Considering these results, if the amount of antimony added is extremely small, and if the antimony is supplied at the same time as the GaInNAs layer growth, the improvement in the GaInNAs crystal properties is thought to be rather small.

The addition of TMSb to the MOCVD-GaInNAs shown in FIG. 3 will be described. The temperature for annealing is varied for various samples grown with different levels of the parameter ([TMSb]/([TMSb]+[TBAs]), or in other words at different flow rate ratios of TMSb. The results of a photoluminescence evaluation performed later at room temperature are shown below. The three graphs are plots with the annealing temperature on the horizontal axis and the photoluminescence wavelength, strength, and FWHM on the vertical axis. The dotted line shows the results for the reference sample under growth conditions where TMSb is not added. The annealing temperature dependency of the photoluminescence emission wavelength (FIG. 3A) shows that the GaInNAs emission wavelength becomes shorter than the reference. The emission intensity (FIG. 3B) is larger than the reference, but this is because the N entrapment effectiveness of the GaInNAs has dropped and the N composition is lower. The FWHM (FIG. 3C) also does not show a noticeable difference from the reference. Therefore, methods where TMSb is supplied at the same time as the GaInNAs quantum well layer growth have lower GaInNAs N entrapment efficiency. As a result, the improvement in optical properties of the GaInNAs is thought to be relatively small.

[Test Case 2]

GaInNAs/GaAs single quantum well (SQW) structure crystal is grown on a GaAs substrate using the MOVPE method. TEGa, TMIn, DMHy, and TBAs are used as the raw materials for Ga, In, N, and As respectively. The substrate is a silicon doped GaAs (100) surface 2° off substrate. A 200 nanometer (200 nm) undoped GaAs buffer layer, followed by a 7 nanometer (7 nm) undoped GaInNAs quantum well structure, and a 100 nanometer (100 nm) undoped GaAs cap layer are grown on a GaAs substrate. The growth temperature of the GaInNAs quantum well structure is 510° C., the growth speed is 1 μm/hour, the DMHy/(DMHy+TBAs) ratio is 0.97, and the growth pressure is 76 torr. The composition of the GaInNAs quantum well layer is 66% Ga and 34% In.

After epitaxial growth of these layers, thermal annealing is performed using a MOVPE oven (in-situ). The thermal annealing is performed in a TBAs environment (TBAs flow rate: 1.6E-4 mole/min) at three levels of annealing temperatures, namely 570° C., 620° C., and 670° C. The annealing time is 10 minutes. For comparison, an “as-grown” test sample which is not thermally annealed is also produced at the same time.

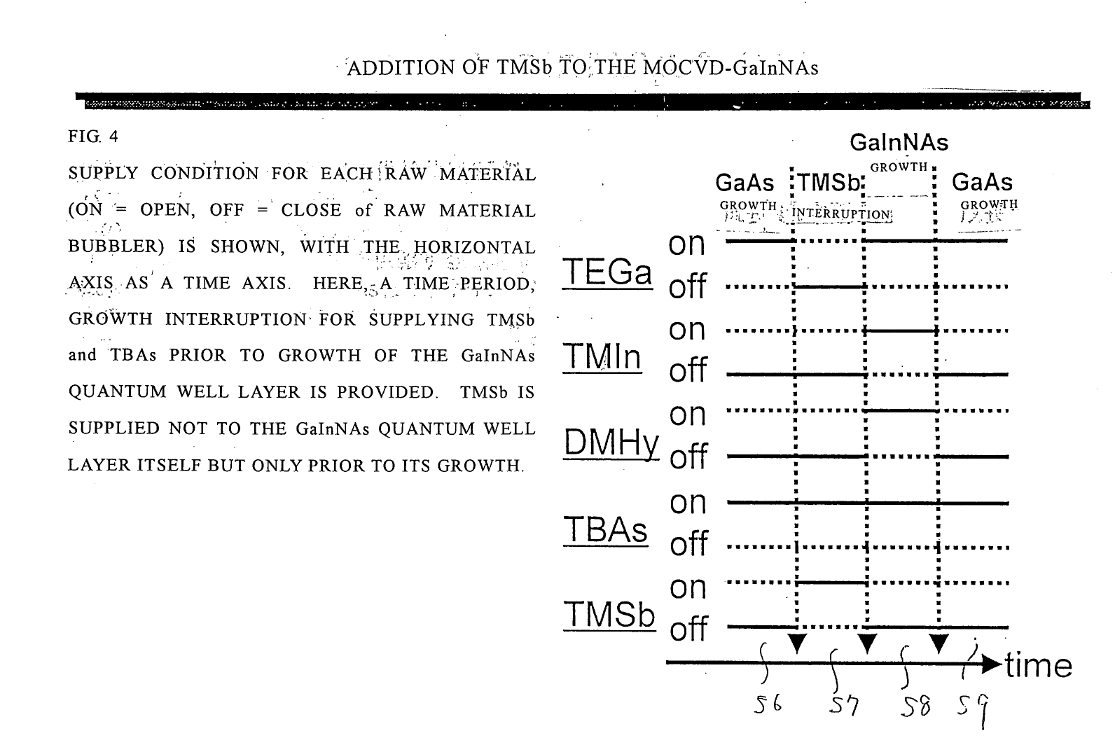

FIG. 4 is a drawing showing a time chart showing the raw material gas flow for the crystal growth of a GaInNAs quantum well structure. With the crystal growth of this GaInNAs quantum well layer, a time period (growth interruption) for TMSb (trimethyl antimony), which is the antimony raw material supplied, is provided just before the GaInNAs layer is grown. During this growth interruption time period, TBAs, another metalorganic raw material gas, is supplied in addition to the TMSb. The reason that TBAs is supplied during this growth interruption period is to prevent the release of arsenic from the epitaxial growth surface. Three levels of antimony are provided, namely 0.15%, 1.5%, and 13%, based on the ratio of ([TMSb]/([TMSb]+[TBAs]) as a parameter. Furthermore, when the level of antimony is 0.15% or 13%, only a growth interruption period is 12 seconds is used, and when the level of antimony is 1.5%, three time periods of 1.2 seconds, 12 seconds, and 120 seconds are used to make test samples.

In Process S6, a first GaAs film is produced. At this time, TEGa and TBAs are used as the raw material gas. In Process S7, a GaInNAs film is produced. At this time, TEGa, TMIn, DMHy, TBAs, and TMSb are used for the raw material gas. In Process S8, the second GaAs film is formed. At this time, TEGa and TBAs are used for the raw material gas. In Process S8, the second GaAs film is formed. At this time, TEGa and TBAs are used for the raw material gas.

In this embodiment, a step to provide TMSb is provided before growing the GaInNAs film which follows the first GaAs film growth. In this step, in addition to supplying TMSb, arsenic can be provided using TBAs for instance in addition to supplying TMSb. Alternatively at this time, in this step, phosphorus (P) and arsenic (As) can be provided using TBP and TBAs in addition to a supply of TMSb for instance.

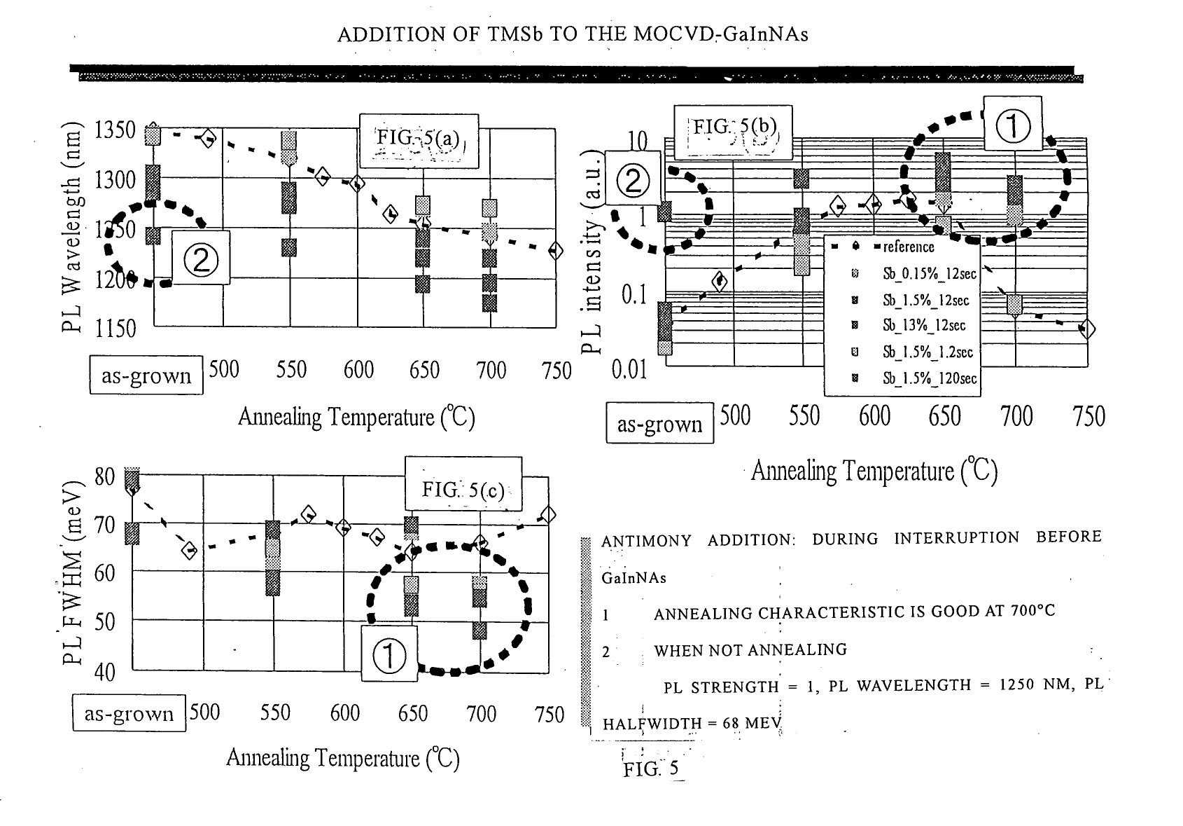

The photoluminescence evaluation of the optical properties at room temperature of the GaInNAs/GaAs quantum well structure crystals. FIG. 5 is a drawing showing the photoluminescence measurement results for a quantum well structure.

As a result, GaInNAs crystal properties are improved in the following two areas. (1) First, when the annealing temperature is at 700° C., the PL emission strength is an order of magnitude larger than the reference. Furthermore, the FWHM of the PL emission is 10 milli-electron volts (10 meV) narrower, thus showing improved GaInNAs crystal properties (FIG. 5B, FIG. 5C). (2) When the level of antimony is such that the ratio ([TMSb]/([TMSb]+[TBAs]) is at 13%, even the unannealed (as-grown) case provided sufficient PL emission strength and FWHM (PL emission strength is approximately 1, the FWHM is no greater than 70 meV) (Refer to FIG. 5B and FIG. 5C). From these results, and it can be seen that a reduction in the N entrapment efficiency in the GaInNAs layer and improved GaInNAs crystal properties can be obtained by providing a time period (growth interruption) for supplying antimony prior to growth of the GaInNAs layer rather than supplying the antimony during the growth of the GaInNAs layer.

TMSb addition to MOCVD-GaInNAs shown in FIG. 5 will be described. Using the TMSb supply method shown in FIG. 4, samples are grown with a change in the parameter ([TMSb]/([TMSb]+[TBAs]), or in other words the flow ratio of TMSb, and the samples are annealed at different temperatures. The results of a room temperature photoluminescence evaluation are as shown below. The three graphs are plots with the annealing temperature on the horizontal axis and PL emission wavelength, strength, and FWHM on the vertical axis. The dotted line represents a reference sample with growth conditions where TMSb is not added. As a result, GaInNAs crystal properties are improved in the following two areas. (1) First, when the annealing temperature is at 700° C., the PL emission strength is an order of magnitude larger than the reference. Furthermore, the FWHM of the PL emission is 10 milli-electron volts (10 meV) narrower, thus showing improved GaInNAs crystal properties (FIG. 5B, FIG. 5C). The reference tends to have lower strength and a larger FWHM when annealed at 700° C. rather than at 650° C. This shows that the structure of the GaInNAs quantum wells is destroyed and crystal properties are degraded by the high 700° C. annealing temperature. In contrast, when TMSb is added, crystal properties are sufficiently maintained even after annealing at 700° C., showing an improvement when compared to the reference. (2) When the level of TMSb is such that the ratio ([TMSb]/([TMSb]+[TBAs]) is at 13%, even the unannealed (as-grown) case provided sufficient PL emission strength and FWHM (PL emission strength is approximately 1, FWHM is no greater than 70 meV) (Refer to FIG. 5B and FIG. 5C). From these results, it can be seen that a reduction in the N entrapment efficiency in the GaInNAs layer and improved GaInNAs crystal properties can be obtained by providing a time period (growth interruption) for supplying antimony prior to growth of the GaInNAs layer rather than supplying the antimony during the growth of the GaInNAs layer.

### Second Embodiment

GaInNAs is expected to be used as a long wavelength band semiconductor laser for optical communication which can be epitaxially grown on a GaAs substrate. Currently, there is an issue of how to increase the optical properties such as photoluminescence strength and FWHM using GaInNAs in order to achieve further improvements in the laser properties such as threshold value. Therefore, the effect on the GaInNAs PL emission wavelength, strength, and FWHM by adding antimony during GaInNAs growth by the MOVPE method is evaluated.

In tests by the inventors, a GaInNAs/GaAs single quantum well structures are grown by the MOVPE method. The raw materials used are TEGa, TMIn, TBAs, and DMHy, with TMSb (trimethyl antimony) used as an antimony additive. The growth pressure is 76 torr and the substrate temperature is 510° C. Two cases are evaluated, one where the antimony additive is added during the GaInNAs layer growth, and one of which is added for a specific period of time only immediately prior to growing the GaInNAs layer. After the GaInNAs layer growth, a 10 minute anneal is performed in a TBAs environment in a MOVPE oven. A GaInNAs layer is grown with different amounts and times of TMSb addition, and the PL emission properties at room temperature are evaluated.

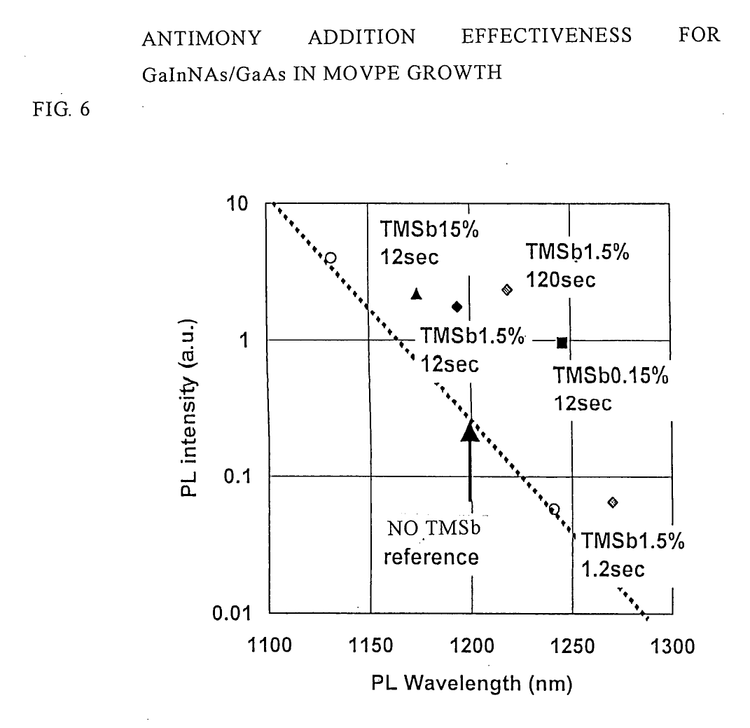

FIG. 6 is a drawing showing the photoluminescence (PL) strength of GaInNAs which has been annealed at 700° C. The horizontal axis shows the PL wavelength (in nanometers) and the vertical axis shows the PL strength.

First when antimony is added during the GaInNAs layer growth, the PL wavelength shortened in correlation with the quantity of additive. During MOVPE growth, the N entrapment efficiency of the GaInNAs is reduced by the addition of antimony. Next, when antimony is added for a fixed period of time only immediately prior to growing the GaInNAs layer, there is a similar shortening of the PL wavelength, but as shown in FIG. 1, when compared to the reference where TMSb is not used, improved strength and FWHM results are obtained for the PL properties after annealing at 700° C. From these results, it can be seen that when growing GaInNAs/GaAs by the MOVPE method, optical properties are improved by the addition of antimony, and particularly by addition to the interface.

### Third Embodiment

In order to be able to improve the crystal properties even during the crystal growth of GaInNAs using the MOVPE method, the addition of antimony (Sb) is used. Antimony (Sb) is supplied prior to growing the GaInNAs layer. A large improvement in the crystal properties is obtained by providing antimony (Sb) to the crystal surface prior to growing the GaInNAs layer. In the preferred embodiment, the addition of antimony is not performed during the growth of the GaInNAs layer, but rather prior to the growth of the GaInNAs layer.

The method of growing a GaInNAs layer on a substrate comprises the step of providing antimony (Hereinafter referred to as Process A) immediately prior to the step of growing the GaInNAs layer. By providing antimony, it is thought that the antimony will adhere to the surface of the III-V semiconductor. Three-dimensional growth of the GaInNAs interface can be controlled by adding antimony. This is because of the “surfactant effect” of the antimony. Furthermore, antimony does not need to be added at the same time as the GaInNAs layer growth process, but rather the effect can be sufficiently obtained by adding immediately prior to the GaInNAs layer growth process. In the preferred embodiment, after the process of adding antimony in a film forming device is completed, the process of growing a GaInNAs layer on the surface of the III-V semiconductor is then performed in the same chamber.

In Process A, a raw material comprising a Group V element (such as arsenic or phosphorus) is simultaneously provided. However, Process A normally involves growing crystals at high temperatures around 500° C., so the Group V elements of arsenic or phosphorus are easily disassociated from the substrate or the crystal growth layer under these conditions. In order to prevent this, a raw material comprising a Group V element is provided at the same time as the raw material comprising antimony is provided. In a preferred embodiment, a metalorganic raw material is used as the raw material comprising elemental arsenic or the raw material comprising elemental phosphorus.

Crystal growth is performed using the MOCVD method, the MBE method, or the epitaxial growth method. These methods are effective regardless of the type of crystal growth.

The sustain time for Process A is no less than 1 second. In testing by the inventors, the optical properties (photoluminescence properties) of the GaInNAs after crystal growth is evaluated for Process A sustain times of 1.2 seconds, 12 seconds, and 120 seconds. At sustain times of 12 seconds and 120 seconds, the photoluminescence strength is dramatically increased as compared to GaInNAs (reference) where the crystal growth does not include Process A. Even for the case where a sustain time of 1.2 seconds is used, the photoluminescence strength is favorable. Furthermore, even sustain times of around one second are possible.

When a quantity X of antimony is supplied in Process A, supply quantity X is preferably greater than or equal to zero (0.0≦X). Furthermore, supply quantity X is preferably no greater than 1 (X≦1.0). X=(supply quantity of antimony per time unit)/((supply quantity of antimony per time unit)+(supply quantity of arsenic per time unit)). In tests by the inventors, the optical properties (photoluminescence properties) of GaInNAs is evaluated after crystal growth where the time of Process A is 12 seconds and X is 0.0015, 0.015, and 0.15. At all levels of X, the photoluminescence strength is higher than when compared with the GaInNAs (reference) where crystal growth does not include Process A.

In a preferred embodiment, a GaAs substrate can be used as the substrate. Furthermore, a GaInNAs layer is grown on the surface of a III-V semiconductor which is GaAs. This III-V semiconductor can be a III-V semiconductor comprising at least nitrogen, or can be a III-V semiconductor comprising at least gallium, indium, or arsenic.

In a preferred embodiment, InP substrate can be used as the substrate. Furthermore, a GaInNAs layer is grown on the surface of a III-V semiconductor which is InP. This III-V semiconductor can be a III-V semiconductor comprising at least nitrogen, or can be a III-V semiconductor comprising at least gallium, indium, or arsenic.

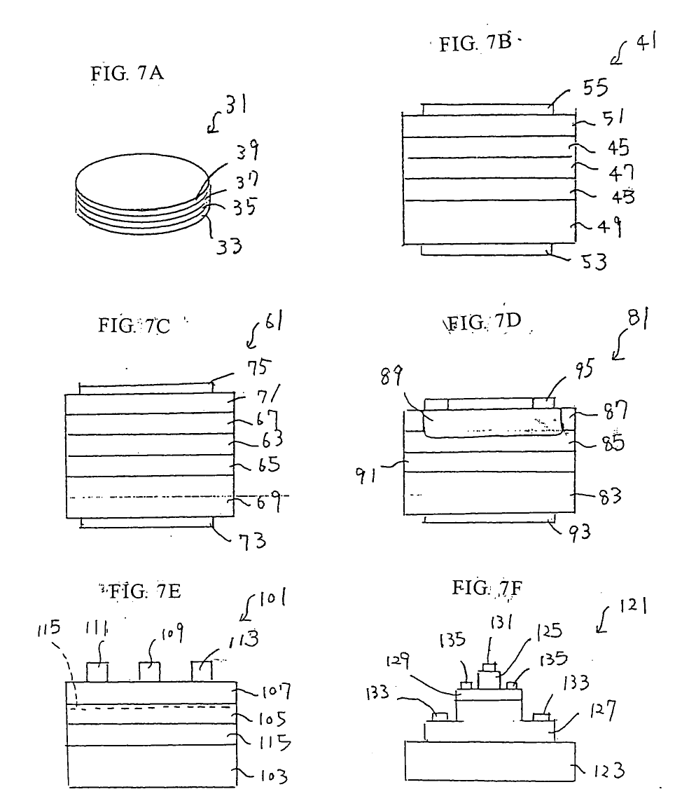

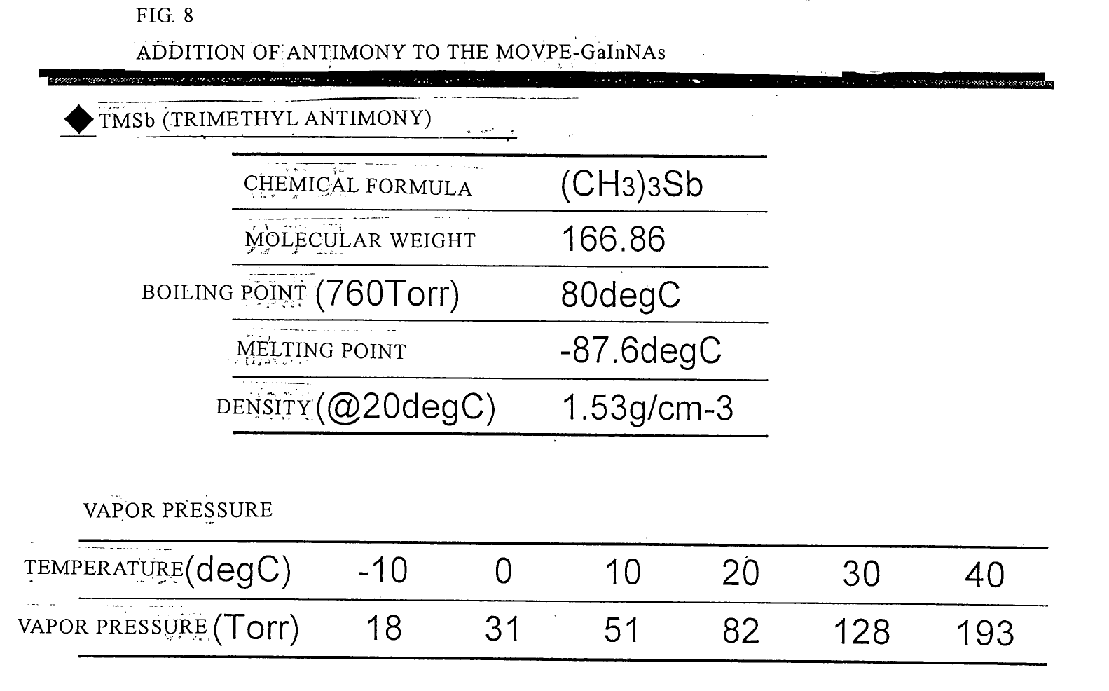

In a preferred embodiment, an epitaxial wafer comprises a GaInNAs layer provided on a substrate. FIG. 7A is a drawing showing an epitaxial wafer. Epitaxial wafer 31 may comprise a substrate 33 and one or more III-V compound semiconductor films 35, 37, 39 provided on this substrate, at least one layer of the III-V compound semiconductor films 35, 37, 39 may be a GaInNAs layer. This GaInNAs layer is formed by the growth methods described above.

A semiconductor device comprises a GaInNAs layer formed by the growth methods described above. This GaInNAs layer is grown by the growth methods described above. A preferred embodiment of the semiconductor device is shown below.

In a preferred embodiment, a semiconductor optical device comprises an active layer which comprises a GaInNAs layer. FIG. 7B is a drawing showing a semiconductor optical device. This semiconductor optical device 41 comprises a first conductive semiconductor layer 43, a second conductive semiconductor layer 45, and an active layer 47 comprising a GaInNAs layer and provided between the first conductive semiconductor layer 43 and the second conductive semiconductor layer 45, and the semiconductor layer is formed using growth methods described above. The semiconductor optical device 41 can also comprise a supporting base 49, a contact layer 51, an electrode 53 which is a cathode electrode, and an electrode 55 which is an anode electrode. Examples of semiconductor optical devices include for instance, semiconductor optical amplifiers, modulators, and light guiding devices or the like.

In a preferred embodiment, a semiconductor laser comprises an active layer comprising a GaInNAs layer. FIG. 7C is a drawing showing a semiconductor laser. Semiconductor laser 61 comprises a first clad layer 65, a second clad layer 67, and an active layer 67 which comprises a GaInNAs layer and is provided between the first clad layer 65 and a second clad layer 67, and the GaInNAs layer is grown using growth methods described above. The semiconductor laser 61 may also comprise a supporting base 69, a contact layer 71, an electrode 73 which is a cathode electrode, and an electrode 75 which is an anode electrode. Examples of semiconductor lasers include DFB type semiconductor lasers, Fabry-Perot semiconductor lasers, and plane emitting lasers or the like.

In a preferred embodiment, a light receiving device comprises a light receiving device layer comprising a GaInNAs layer. FIG. 7D and is a drawing showing a light receiving device. This semiconductor light receiving device 81 comprises a light receiving device semiconductor layer 85 comprising a GaInNAs layer which is provided on a supporting base 83, and the GaInNAs layer is grown by a growth method described above. Semiconductor light receiving device 81 may also comprise a window layer 87, an anode region 89, a buffer layer 91, an electrode 93 which is a cathode electrode, and an electrode 95 which is an anode electrode. Examples of light receiving devices include pin type photodiodes and APD type photodiodes.

In a preferred embodiment, a high electron mobility transistor comprises a GaInNAs layer grown using a growth method described above. FIG. 7E is a drawing showing a high electron mobility transistor. The high electron mobility transistor 101 is comprised of an electron drive layer 105 through which carriers (two-dimensional electron gas 115) flows and which is provided on a supporting base 103, an electron source layer 107, a first electrode 109 which is a gate electrode for controlling the flow of the carriers and which is provided on the electron source layer 107, a second electrode 111 which is a source electrode provided on the supporting base 103, a third electrode 113 which is a drain electrode provided on the supporting base 103, and a buffer layer 115, and at least one of the electron drive layer 105 and the electron source layer 107 comprises a GaInNAs layer, and the GaInNAs layer is grown using growth methods described above.

In a preferred embodiment, a heterojunction bipolar transistor comprises a GaInNAs layer grown by a growth method described above. FIG. 7F is a drawing show a heterojunction bipolar transistor. The heterojunction bipolar transistor 121 comprises an emitter layer 125 which is provided on a supporting base 123, a collector layer 127 provided on the supporting base 123, and a base layer 129 provided between the collector layer 127 and emitter layer 125, and at least one of the emitter layer 125, layer 127, or base layer 129 comprises a GaInNAs layer, and the GaInNAs layer is grown by a growth method described above. The heterojunction bipolar transistor 121 can also comprise an emitter electrode 131, a collecting electrode 133, and a base electrode 135.

### Fourth Embodiment

The growth of a GaInNAs film/GaAs film using antimony additive on GaInNAs/GaAs using the MOVPE growth method will be described. GaInNAs is anticipated to become a material for long wavelength band laser diodes and for optical devices such as VCSEL or the like. As the quantity of N increases in the GaInNAs crystals, the optical properties are degraded. Under these conditions, the method of improving the optical properties in the wavelength band of 1.2 to 1.3 μm has become a problem. In order to improve the crystal properties of the GaInNAs, an investigation has been made to improve the crystal properties using the following means. Furthermore, research has been performed concerning the addition of antimony in GaInNAs quantum wells using MOVPE growth in order to improve the crystal properties of the GaInNAs. A method of annealing after GaInNAs Crystal growth (Post growth Neil) is a means for improving the crystal properties of the GaInNAs. By this annealing, the photoluminescence strength is increased and the photoluminescence FWHM is reduced. By optimizing the annealing conditions, the optical properties can be improved. Furthermore, increasing the purity of the raw material is also necessary for improving the optical properties. Furthermore, by adding multiple elements (such as adding phosphorus), an improvement in optical properties can be anticipated. In this embodiment, the addition of antimony (Sb) in GaInNAs using MOVPE grows will be described. By this addition of antimony, a change in the optical properties of the GaInNAs crystals and uses for the improved GaInNAs Crystal properties will be described.

FIG. 8 is a drawing showing the major physical values of antimony raw material. Trimethyl antimony (TMSb) for example, is used as the antimony raw material. The MOVPE growth method is used for crystal growth. The temperature of a high-temperature chamber is set to approximately ambient temperature, and TMSb is introduced using bubbling.

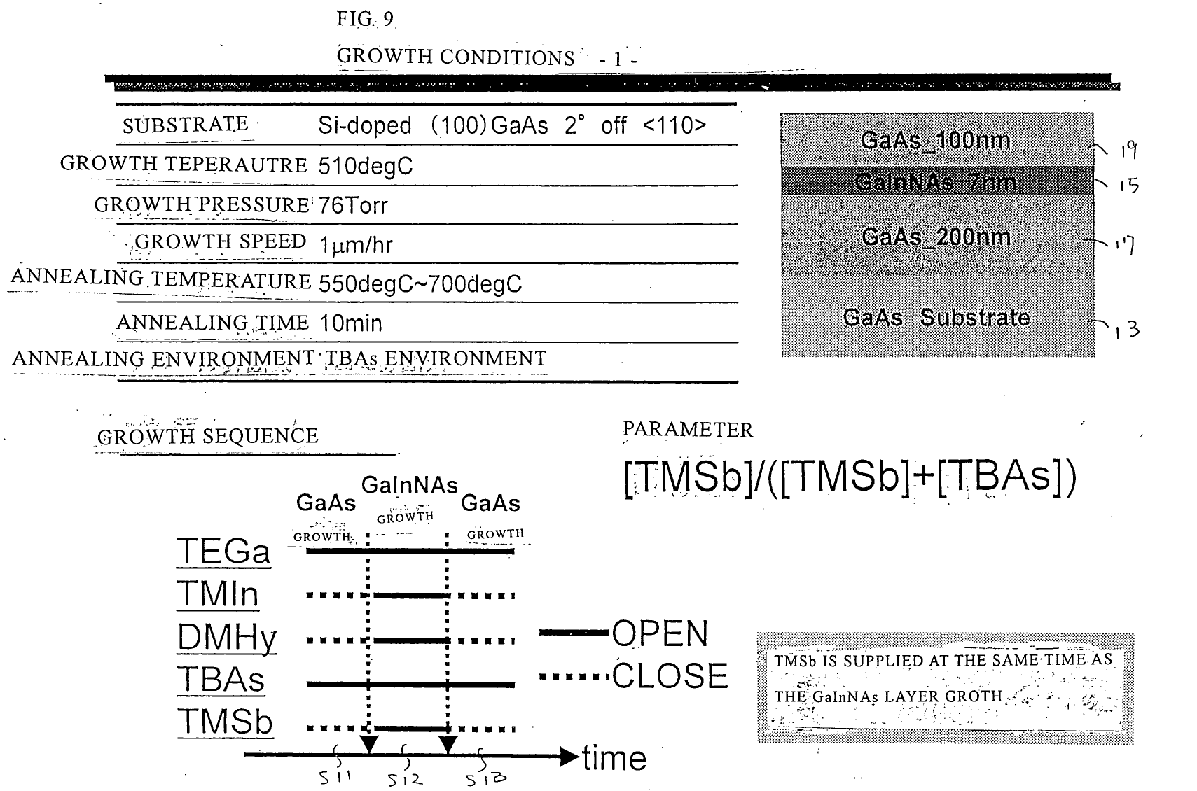

FIG. 9 is a drawing showing the growth conditions, growth sequence, and created device of the first test. This device comprises a GaInNAs layer 15 which is provided on a GaAs substrate 13, a first GaAs semiconductor layer 17, and a second GaAs semiconductor layer 19. As shown in the growth sequence, a first GaAs semiconductor layer 17 is grown using raw material gasses TEGa and TBAs in Process S11. In Process S12, the raw material gasses TEGa, TMIn, DMHy, TBAs, and TMSb are used for growing a GaInNAs layer 15. In Process S12, antimony is supplied during the growth of the GaInNAs layer 15. In Process S13, a second GaAs semiconductor layer 19 is grown using raw material gasses TEGa and TBAs. Growth is performed using the ratio between TMSb and the [sum of TBA TMSb] as a parameter.

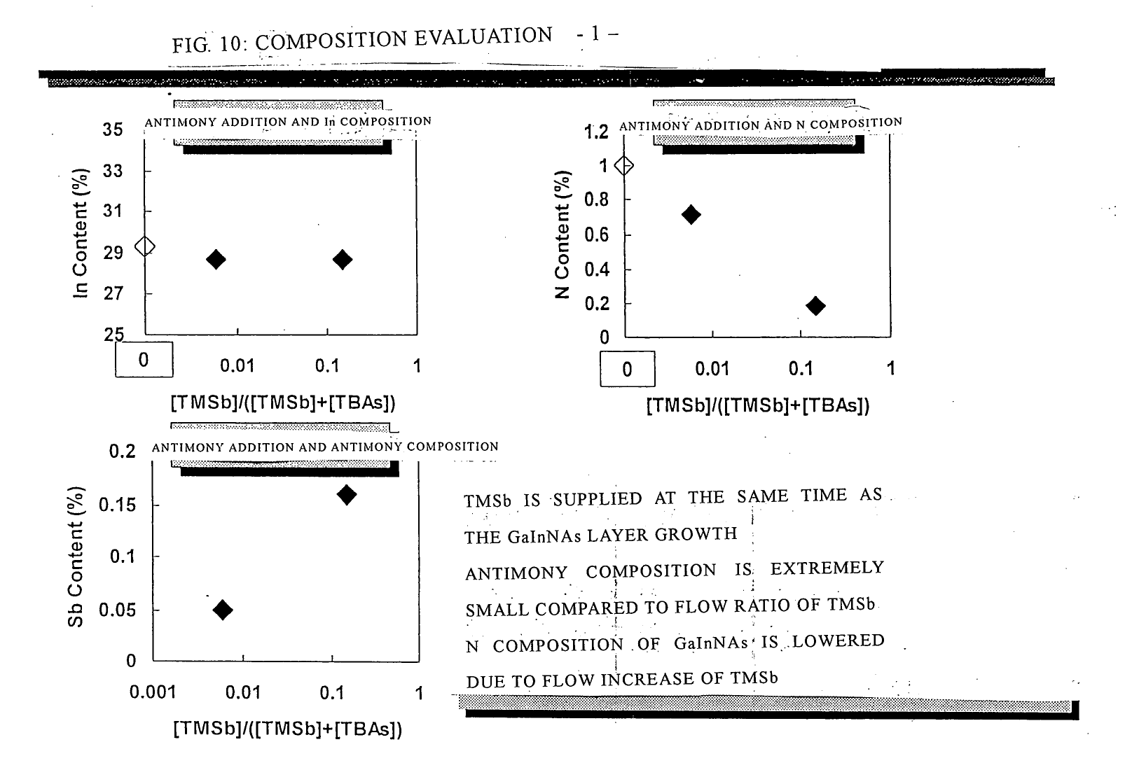

FIG. 10 is a drawing showing the structure of GaInNAs crystals grown while supplying TMSb at the same time as the GaInNAs layer growth. A composition evaluation of samples created while changing the aforementioned parameter is performed using a SIMS analysis. The three graphs are plots with the added quantity of TMSb on the horizontal axis and the composition of In, N, or Sb on the vertical axis. The outlining identifies a reference case where antimony is not added. From this evaluation, it can be seen that the formulation quantity of antimony is extremely small compared to the flow ratio of TMSb, but there is dependency on that quantity, and that as the TMSb flow ratio increases, the N composition of the GaInNAs becomes smaller. By these results, the following points can be understood: (1) the formulation quantity of antimony is much smaller than the flow ratio of TMSb; and (2) as the flow rate of TMSb increases, the nitrogen composition of the GaInNAs tends to decrease.

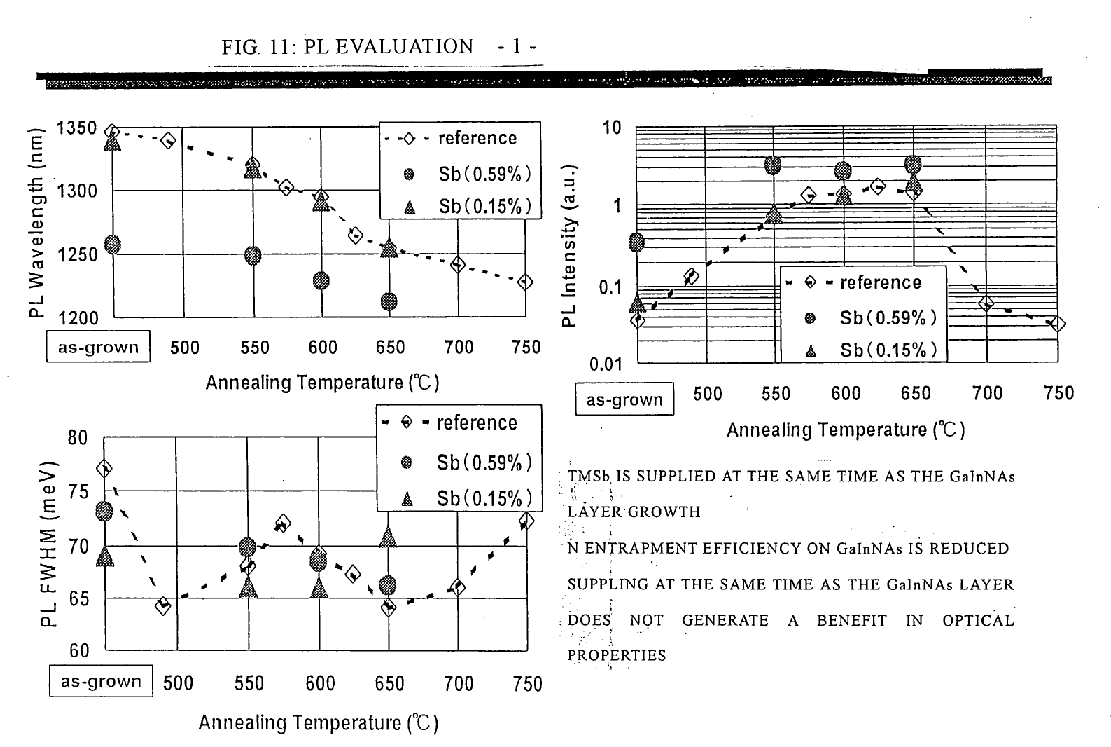

FIG. 11 is a drawing showing the PL properties of a GaInNAs layer grown while supplying TMSb at the same time as the GaInNAs layer growth. Next, the annealing temperature is changed for samples grown at different parameter values. The results of a photoluminescence evaluation later performed at room temperature are shown below. The three graphs are plots with the annealing temperature on the horizontal axis and the photoluminescence emission wavelength, strength, and FWHM on the vertical axis. The dotted line represents a reference sample which had growth conditions where TMSb is not added. Looking at the annealing temperature dependency of the photoluminescence emission wavelength, as is shown by the previous composition evaluation, the emission wavelength from the GaInNAs is shorter for the reference. The emission strength is stronger than the reference, but this is because the N composition of the GaInNAs is lower. The FWHM does not show a noticeable difference compared to the reference. From this is thought that methods where TMSb is supplied at the same time as the GaInNAs Quantum will layer growth have lower efficiency for nitrogen entrapment in the GaInNAs.

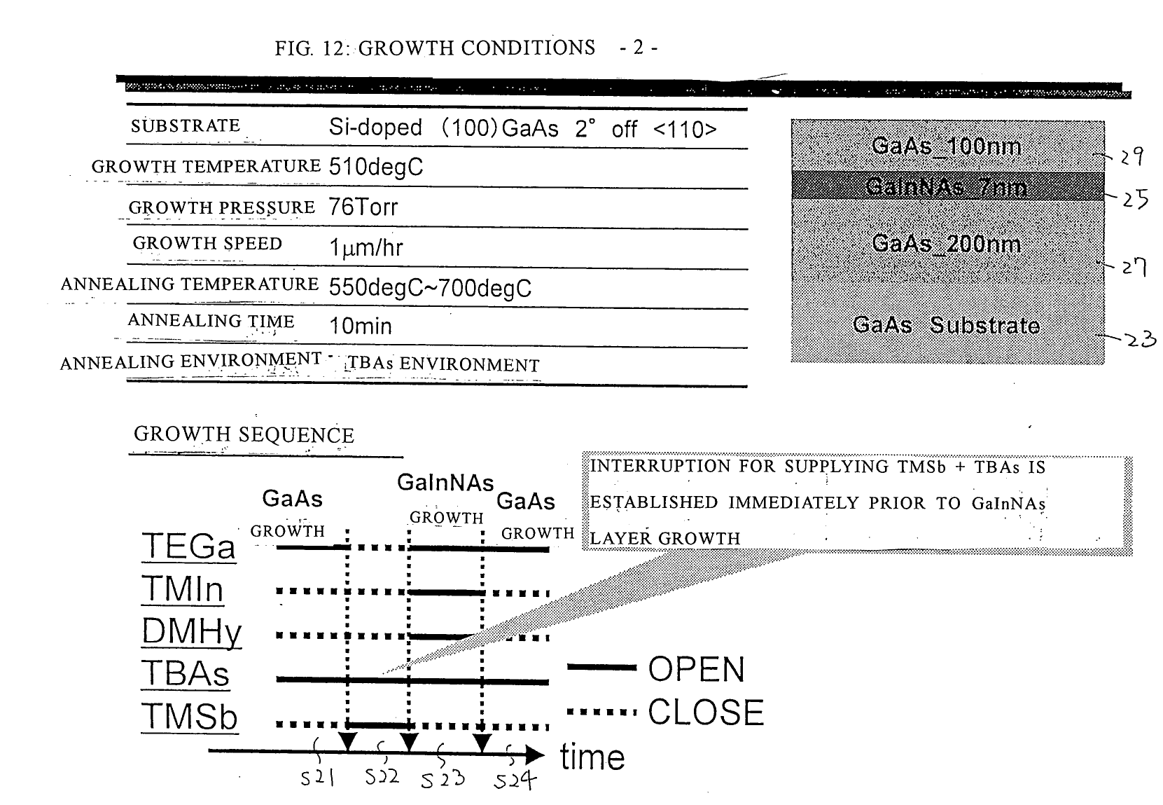

FIG. 12 is a drawing showing the growth conditions, growth sequence, and created device of the second test. This device comprises a GaInNAs layer 25 provided on a GaAs substrate 23, a first GaAs semiconductor layer 27, and a second GaAs semiconductor layer 29. As shown by the growth sequence, the first GaAs semiconductor layer 27 is grown in Process S21 using raw material gasses TEGa and TBAs. In process S22, TBAs and TMSb are supplied to the surface of the first GaAs semiconductor layer 27. In Process S23, the GaInNAs layer 25 is grown using raw material gasses TEGa, TMIn, DMHy, TBAs, and TMSb. Prior to growing the GaInNAs layer 15, antimony is supplied in Process S22. In Process S24, the second GaAs semiconductor layer 29 is formed using raw material gasses TEGa and TBAs. The growth conditions for the second test and the structure of the device identical as the first test, with the following exception. The exception is the method of supplying the TMSb. As shown in the growth sequence, in the second test, a period of time for supplying TMSb and TBA, and a growth interruption are established immediately prior to growing the GaInNAs quantum well layer. The effect of adding the TMSb is obtained by supplying TMSb only prior to growth, and not for the GaInNAs quantum well layer itself. Similarly, growth is performed using the ratio of TMSb to the “sum of TMSb and TBA” as a parameter.

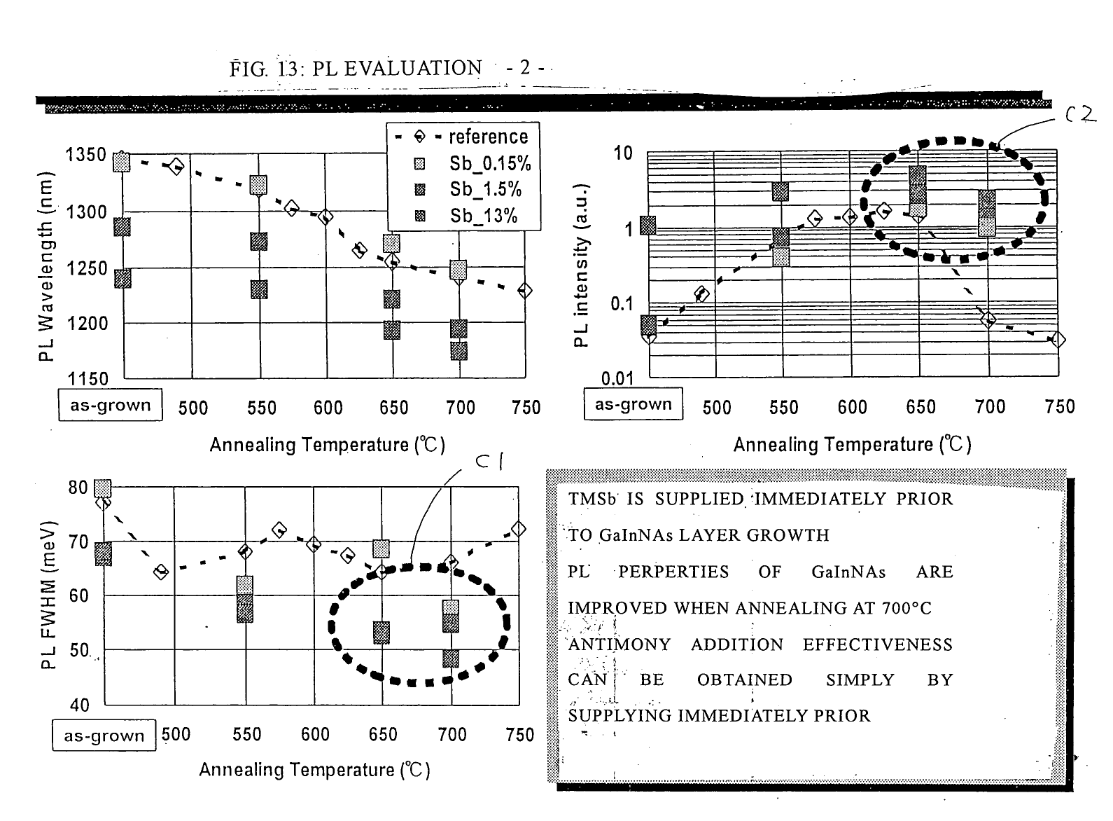

FIG. 13 is a drawing showing the PL properties of a device created by the second test. Annealing a different temperatures is performed on various devices grown at different values of the aforementioned parameter, and the results of a photoluminescence evaluation at room temperature are as shown below. Similar to the previous case, the three graphs are plots with the anneal temperature on the horizontal axis, and the photoluminescence emission wavelength, strength, and FWHM on the vertical axis. The broken line represents a reference sample with growth conditions where TMSb is not added. From the results of the annealing temperature dependency of the emission wavelength, (1) similar to the first test, the photoluminescence emission wavelength is shorter only when TMSb is added prior to growing the GaInNAs quantum well layer. (2) The important point to notice is the difference compared to the reference when annealing at a temperature of 700° C. shown by the broken lines C1 and C2. With the reference, the strength tends to be lower and the FWHM larger when annealing is performed at 700° C. rather than at 650° C. This is because the structure of the GaInNAs quantum wells is destroyed and crystal properties degraded during high temperature annealing at 700° C. In contrast, when TMSb is added, even when annealing at 700° C., sufficient emission strength is maintained and the results showed that the FWHM also smaller than the reference, so the photoluminescence properties are improved compared to the reference.

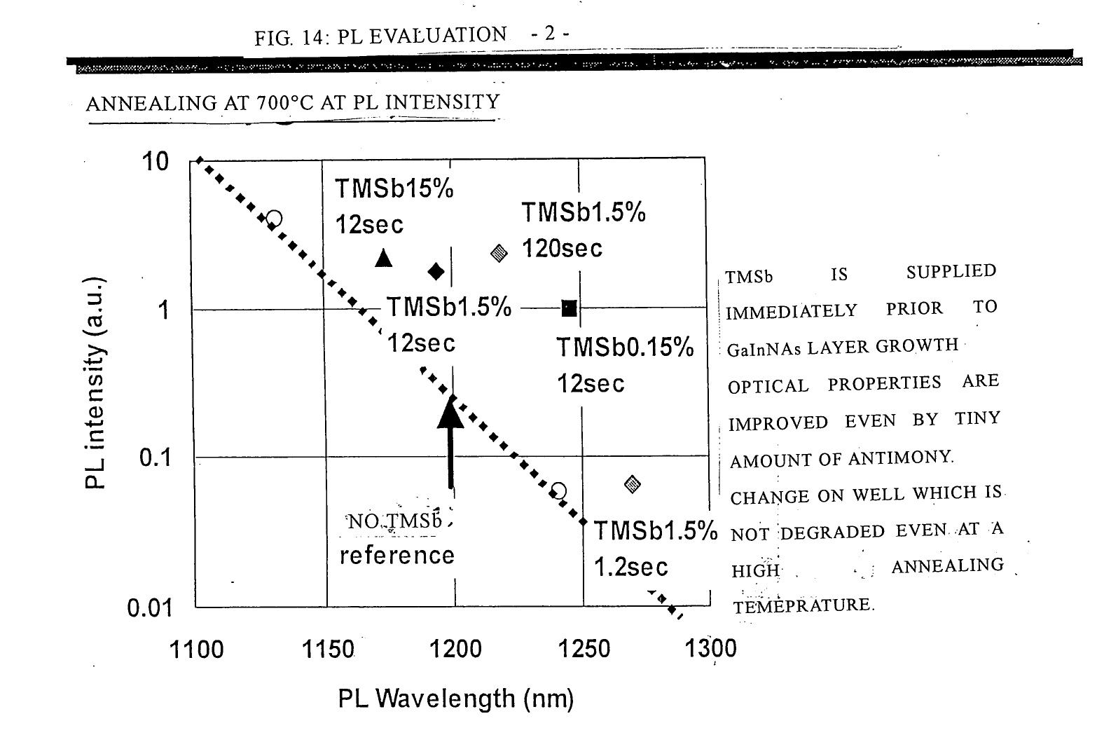

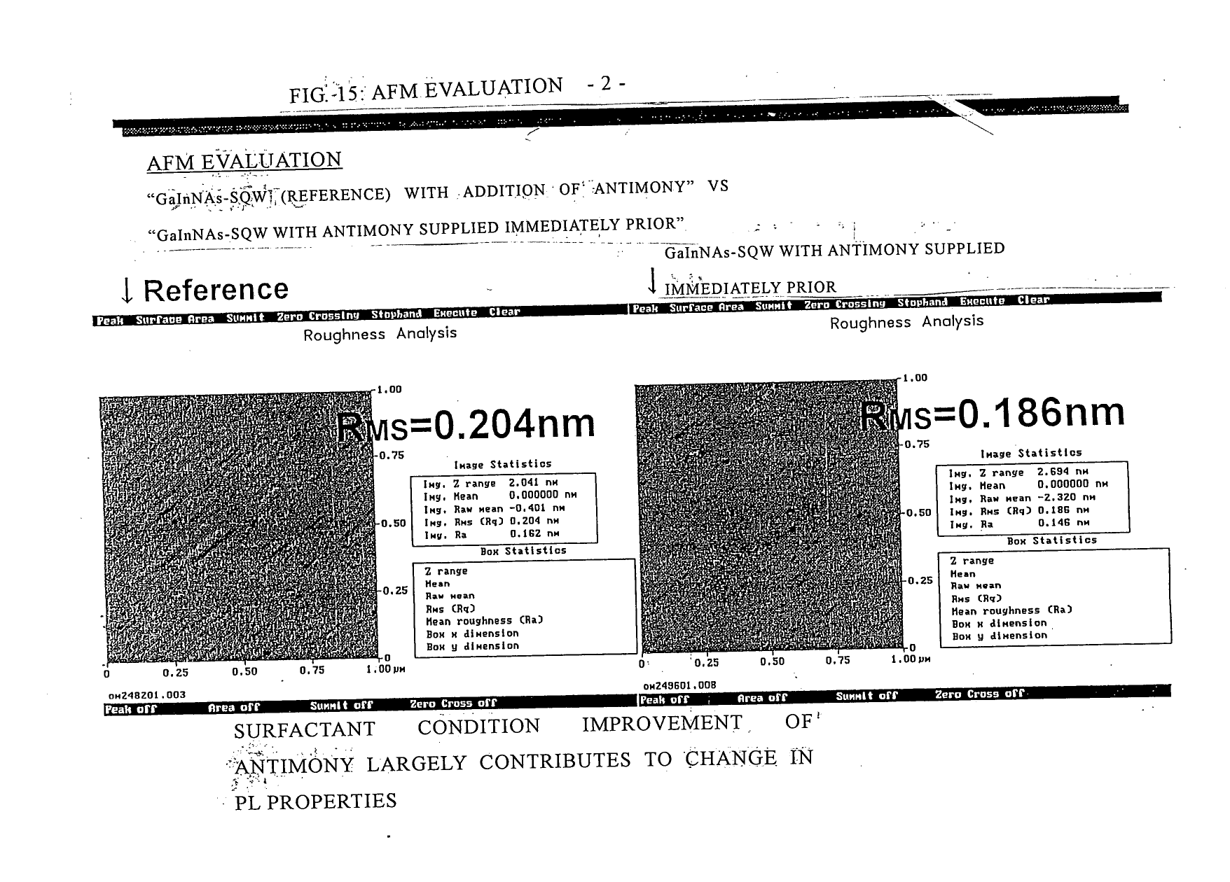

FIG. 14 is a drawing showing the photoluminescence (PL) strength of GaInNAs which has been annealed at 700° C. This graph is a plot of a photoluminescence evaluation with the photoluminescence emission wavelength on the horizontal axis and the photoluminescence emission strength on the vertical axis for various samples of GaInNAs-SQW annealed at 700° C. The photoluminescence emission wavelength varied because of the difference in the N composition of the GaInNAs quantum wells, but the dotted line shows the change in emission wavelength and emission strength for the case of the reference where TMSb is not added. Compared to the reference, when TMSb is added at various conditions immediately prior to growing the GaInNAs quantum well layer, the data is located above and to the right of the reference. In other words, by supplying even extremely small quantities of TMSb immediately prior to growing the GaInNAs quantum well layer, the optical properties of the GaInNAs quantum wells will be improved and the wells are thought to be converted to quantum wells which do not degrade even when annealed at 700° C.

FIG. 15 is a drawing showing AFM evaluation results. In order to investigate the results of the photoluminescence evaluation and determine what type of quantum well is a quantum well which does not degrade even at high annealing temperatures, an AFM evaluation of the surface of the epitaxial layer of two devices, namely “a GaInNAs-SQW (Reference) without addition of antimony” and “a GaInNAs-SQW with antimony supplied immediately prior”, and the observation results are as shown below. Compared to the reference, when TMSb is added, the RMS which shows the surface roughness, is smaller. When TMSb is supplied immediately prior to growing the GaInNAs quantum well layer, the optical properties are improved, and it is thought that the improvement in the interface condition of the GaInNAs/GaAs quantum well by antimony is a major contributor.

According to the test results, the addition of antimony in GaInNAs quantum well by MOVPE growth is possible using TMSb. By supplying TMSb only prior to growing the GaInNAs quantum well layer rather than by supplying the TMSb at the same time as the GaInNAs quantum well layer growth, the effect of the antimony additive can be sufficiently obtained and the optical properties improved. The change in these optical properties is dependent on the quantity of antimony. From this, is thought that the improvement in the optical properties is because of the effect of antimony on the interface of the GaInNAs quantum well, or in other words, the improvement in the GaInNAs quantum well interface because of the surfactant effect of antimony.

As described above, in literature 1, the crystal growth method is restricted to the MBE method because thallium must be supplied. It is difficult to supply thallium using the MOVPE method. This is because either with the MOVPE method (metalorganic epitaxial growth) or the MBE method (molecular linear epitaxial growth), the base is used for the GaInNAs crystal growth. When thallium is supplied during GaInNAs crystal growth, the thallium metal or the like can be a raw material in the MBE method. In contrast, at the present time, the optimal organic metal which can supply thallium in the MOVPE method has not yet been found, and therefore thallium is difficult to supply.

In literature 1, the GaInNAs layer is said to be grown in the presence of antimony and that the quantity of antimony adulteration is at a level which can be ignored. However, when the quantity of antimony is extremely small, the improvement in the crystal properties will be extremely small. Furthermore, even when the GaInNAs layer is grown in a location where little antimony is present, the emission wavelength or the like of the GaInNAs will change dramatically, and the improvement in the crystal characteristics will not be very significant. This is because when using the MOVPE up a method or the MBE method or growth GaInNAs quantum well structures, if the growth occurs in the locations where antimony is present and the level of antimony adulteration is small enough to be able to be ignored, then the improvement in the crystal properties of the caused by the addition of antimony will be extremely small. When antimony is added to GaInNAs using the MBE method, the improvement in the crystal properties first appears at a level where the antimony is approximately 2% of the composition of the Group V elements, which is a level which cannot be ignored. Furthermore, with the MOVPE method, even if the quantity of antimony adulteration is small, a shortening of the emission wavelength of the GaInNAs occurs and the improvement in crystal properties is not great.

Having described the principles of the present invention using preferred embodiments, but the present invention can be modified in the arrangement or other details by those skilled in the art so long as they do not deviate from these principles. Therefore, rights are claimed for all modifications and alterations derived from the patent claims or from the spirit of those claims.

1. A method for growing a GaInNAs layer on a supporting base, comprising the steps of:
supplying antimony to the surface of the supporting base; and
after supplying the antimony, growing the GaInNAs layer on the surface.

2. The method according to claim 1, wherein the GaInNAs layer is grown after supplying the antimony.

3. The method according to claim 1 or claim 2, wherein raw materials comprising Group V elements are simultaneously supplied in addition to the antimony in the step of supplying antimony.

4. The method according to any of claim 1 through claim 3, wherein the Group V elements are at least either arsenic (As) or phosphorus (P).

5. The method according to any of claim 1 through claim 4, wherein the crystal growth uses any one of the MOCVD method, MBE method, or epitaxial growth method.

6. The method according to any of claim 1 through claim 5, wherein the sustain time for the supply of antimony on the surface of the supporting base is no less than 1 second.

7. The method according to any of claim 1 through claim 6, wherein the quantity X of antimony supplied is greater than or equal to 0 and less than or equal to 1 (0.0≦X≦1.0), where X=(quantity of antimony supplied per unit time)/((quantity of antimony supplied per unit time)+(quantity of arsenic supplied per unit time)).

8. The method according to any of claim 1 through claim 7, wherein the supporting base comprises a GaAs substrate.

9. The method according to any of claim 1 through claim 7, wherein the supporting base comprises a InP substrate.

10. An epitaxial wafer, comprising:
a substrate; and
a GaInNAs layer provided on the substrate, the GaInNAs layer being grown by any of the methods described in claim 1 through claim 9.

11. A semiconductor optical device, comprising:
a first conductive semiconductor layer;
a second conductive semiconductor layer; and
an active layer comprising a GaInNAs layer and provided between the first conductive semiconductor layer and the second conductive semiconductor layer, the GaInNAs layer being grown by any of the methods described in claim 1 through claim 9.

12. A semiconductor laser, comprising:
a first clad layer;
a second clad layer; and
an active layer comprising a GaInNAs layer and provided between the first clad layer and the second clad layer, the GaInNAs layer being grown by any of the methods described in claim 1 through claim 9.

13. A light receiving device, comprising a light receiving semiconductor layer comprising a GaInNAs layer and provided on a supporting base, the GaInNAs layer being grown by any of the methods described in claim 1 through claim 9.

14. A high electron mobility transistor, comprising:
a first semiconductor layer through which a carrier flows and which is provided on a supporting base;
one or more second semiconductor layers;
a first electrode which controls the flow of the carrier which is provided on the first and second semiconductor layers;
a second electrode provided on the first and second semiconductor layers; and
a third electrode provided on the first and second semiconductor layers,
wherein at least one of the first and second semiconductor layers comprises a GaInNAs layer, and the GaInNAs layer is grown by any of the methods described in claim 1 through claim 9.

15. A heterojunction bipolar transistor, comprising:
an emitter layer provided on a supporting base;
a collector layer provided on a supporting base; and
a base layer provided between the collector layer and the emitter layer,
wherein at least one of the emitter layer, the collector layer, and the base layer comprises a GaInNAs layer, and the GaInNAs layer is grown by any of the methods described in claim 1 through claim 9.

16. A semiconductor device, comprising a semiconductor layer comprising a GaInNAs layer and provided on a supporting base, wherein the GaInNAs layer is grown by any of the methods described in claim 1 through claim 9.
